(19) United States
(12) Patent Application Publication
(10) Pub. No.: US 2023/0163044 A1
(43) Pub. Date: May 25, 2023

(54) DISPLAY DEVICE AND MANUFACTURING METHOD FOR THE SAME

(71) Applicant: Samsung Display Co., LTD., Yongin-si (KR)

(72) Inventors: Jong Hyeon CHOI, Yongin-si (KR); Sung Won KIM, Yongin-si (KR); Haeng Won PARK, Yongin-si (KR)

(73) Assignee: Samsung Display Co., LTD., Yongin-si (KR)

(21) Appl. No.: 17/993,252

(22) Filed: Nov. 23, 2022

(30) Foreign Application Priority Data
Nov. 25, 2021 (KR) 10-2021-0164358

(51) Int. Cl. H01L 23/373; H01L 25/16

(52) U.S. Cl. CPC H01L 23/3735; H01L 25/167

(57) ABSTRACT

A display device includes a display layer including a light emitting element, a heat dissipation part disposed on a rear surface of the display layer, the heat dissipation part including a heat dissipation layer, and a resin part sealing at least a portion of the heat dissipation layer. In a plan view, the heat dissipation layer extends by a same length as the display layer or extends farther than the display layer.

### CROSS-REFERENCE TO RELATED APPLICATION(S)

This application claims priority to and benefits of Korean Patent Application No. 10-2021-0164358 under 35 U.S.C. § 119(a), filed on Nov. 25, 2021 in the Korean Intellectual Property Office (KIPO), the entire contents of which are incorporated herein by reference.

### BACKGROUND

### 1. Technical Field

The disclosure generally relates to a display device and a manufacturing method for the same.

### 2. Description of the Related Art

Recently, as interest in information displays has increased, research and development of display devices has been continuously conducted.

### SUMMARY

Embodiments provide a display device and a manufacturing method for the same, which may be configured to improve process performance and reduce a light leakage phenomenon while sufficiently ensuring heat dissipation performance.

In accordance with an aspect of the disclosure, there is provided a display device that may include a display layer including a light emitting element, a heat dissipation part disposed on a rear surface of the display layer, the heat dissipation part including a heat dissipation layer, and a resin part sealing at least a portion of the heat dissipation layer. In a plan view, the heat dissipation layer may extend by a same length as the display layer or may extend farther than the display layer.

The heat dissipation layer may include graphite.

The heat dissipation part may include a cover layer sealing at least one surface of the heat dissipation layer.

The cover layer may include a first cover layer covering a surface of the heat dissipation layer, and a second cover layer covering another surface of the heat dissipation layer.

A surface of the heat dissipation layer may be covered by the cover layer, another surface of the heat dissipation layer may be exposed by the cover layer, and the heat dissipation layer may be disposed between the display layer and the cover layer.

The display device may further include a first area overlapping the heat dissipation layer in plan view, and a second area not overlapping the heat dissipation layer in plan view. In a plan view, the display layer, the heat dissipation layer, and the cover layer may overlap the first area. In a plan view, the resin part and the cover layer may overlap the second area.

In a plan view, the resin part may overlap the heat dissipation layer and the cover layer in a partial area of the first area.

A surface of the display layer may be covered by the heat dissipation layer, and a side surface of the display layer may be covered by the resin part.

The display device may further include a first area overlapping the heat dissipation layer in a plan view, and a second area not overlapping the heat dissipation layer in a plan view. In a plan view, the resin part may overlap the cover layer in each of the first area and the second area.

The heat dissipation layer may extend by a same length as the cover layer or may extend farther than the cover layer in a direction.

The heat dissipation layer may extend farther by a heat dissipation extension length than the display layer. In a plan view, the resin part may overlap the heat dissipation layer and an area in which the heat dissipation extension length may be defined.

The display device may further include an outer film layer disposed on the display layer. The resin part may include a film adjacent surface adjacent to the outer film layer and an outer lower surface disposed at another side of the film adjacent surface. A thickness of the outer lower surface may be greater than a thickness of the film adjacent surface in an extending direction of the outer film layer.

The display device may further include an outer film layer disposed on the display layer. The resin part may include a film adjacent surface adjacent to the outer film layer, and an outer lower surface disposed at another side of the film adjacent surface. The film adjacent surface may have a first thickness from a division point of the first area and the second area in an extending direction of the outer film layer, the outer lower surface may have a second thickness from the division point of the first area and the second area in the extending direction of the outer film layer, and the resin part may have an average thickness defined from the division point of the first area and the second area in the extending direction of the outer film layer. The second thickness may be greater than the average thickness.

The first thickness may be smaller than the average thickness.

In accordance with another aspect of the disclosure, there may be provided a display device that may include a display layer including a light emitting element, a heat dissipation part disposed on a rear surface of the display layer, the heat dissipation part including a heat dissipation layer, an outer film layer disposed on the display layer, and a resin part sealing at least a portion of the heat dissipation layer. The resin part may include a film adjacent surface adjacent to the outer film layer and an outer lower surface disposed at another side of the film adjacent surface. A thickness of the outer lower surface may be greater than an average thickness of the resin part in an extending direction of the outer film layer.

In accordance with still another aspect of the disclosure, there is provided a method for manufacturing a display device. The method may include providing a heat dissipation part on a rear surface of a display layer including a light emitting element, cutting a portion of the heat dissipation part, and providing a resin part. The heat dissipation part may include a heat dissipation layer and a cover layer. The cutting of the portion of the heat dissipation part may include cutting the cover layer. The providing of the heat dissipation part may include disposing the heat dissipation layer to extend by a same length as the display layer or to extend farther than the display layer.

The providing of the resin part may include sealing the heat dissipation layer, and sealing the display layer.

The method may further include disposing an outer film layer on the display layer. The providing of the heat dissipation part may include defining a first area, a second area, and a third area. The first area may overlap the heat dissipation layer in a plan view, and the second area and the third area may not overlap the heat dissipation layer in a plan view. The cutting of the portion of the heat dissipation part may include removing a portion of the outer film layer and a portion of the cover layer, which may overlap the third area in a plan view.

In a plan view, the portion of the outer film layer and the portion of the cover layer, which overlap the third area, may be removed through a same cutting process.

The method may further include disposing a support plate on a rear surface of the heat dissipation part.

The disposing of the support plate may be performed after the providing of the resin part.

The disposing of the support plate may be performed before the providing of the resin part.

The support plate may be attached to the heat dissipation part by a double-sided adhesive part.

The support plate may include a groove area, and be attached to the heat dissipation part by a foam type adhesive part disposed in the groove area.

The providing of the heat dissipation part may include defining a first area, a second area, and a third area. The first area may overlap the heat dissipation layer in a plan view, and the second area may not overlap the heat dissipation layer in a plan view. The providing of the resin part may include filling a space in which the resin part overlaps the second area in a plan view.

The support plate may physically support a bottom of the resin part such that the resin part forms a contact surface with the support plate.

In accordance with still another aspect of the disclosure, there is provided a display device manufactured according to a described method.

### BRIEF DESCRIPTION OF THE DRAWINGS

FIGS. 1 and 2 are perspective and sectional views schematically illustrating a light emitting element in accordance with an embodiment of the disclosure.

FIG. 3 is a plan view schematically illustrating a display device in accordance with an embodiment of the disclosure.

FIG. 4 is a plan view schematically illustrating a sub-pixel in accordance with an embodiment of the disclosure.

FIG. 5 is a schematic sectional view taken along line I-I′ shown in FIG. 4.

FIGS. 6 to 9 are schematic sectional views illustrating a heat dissipation part in accordance with embodiments of the disclosure.

FIG. 10 is a flowchart schematically illustrating a manufacturing method for the display device in accordance with an embodiment of the disclosure.

FIGS. 11 to 13, 15, and 16 are schematic process sectional views illustrating a manufacturing method for the display device in accordance with an embodiment of the disclosure.

FIG. 14 is a schematic enlarged view of area EA1 shown in FIG. 13.

### DETAILED DESCRIPTION OF THE EMBODIMENTS

Example embodiments will now be described more fully hereinafter with reference to the accompanying drawings; however, the disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “comprises”, “comprising”, “has”, “have”, “having”, “includes”, and “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. Similarly, an expression that an element such as a layer, region, substrate or plate is placed “beneath” or “below” another element indicates not only a case where the element is placed “directly beneath” or “just below” the other element but also a case where a further element is interposed between the element and the other element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween. Further, the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

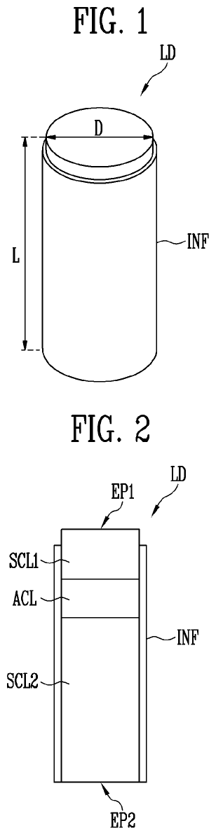

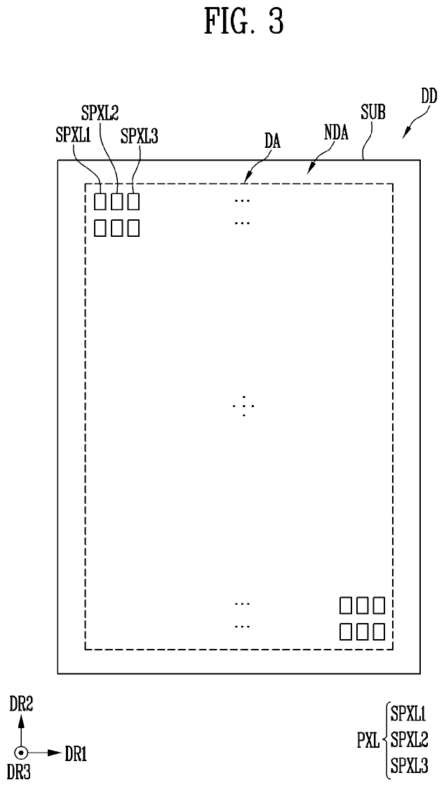

A light emitting element LD included in a display device (see ‘DD’ shown in FIG. 3) in accordance with an embodiment of the disclosure is illustrated in FIGS. 1 and 2. FIGS. 1 and 2 are perspective and sectional views schematically illustrating a light emitting element in accordance with an embodiment of the disclosure. Although a pillar-shaped (or rod-shaped) light emitting element LD is illustrated in FIGS. 1 and 2, the kind and/or shape of the light emitting element LD is not limited thereto.

Referring to FIGS. 1 and 2, the light emitting element LD may include a first semiconductor layer SCL1, a second semiconductor layer SCL2, and an active layer ACL interposed between the first and second semiconductor layers SCL1 and SCL2. For example, assuming that an extending direction of the light emitting element LD is a length L direction, the light emitting element LD may include the first semiconductor layer SCL1, the active layer ACL, and the second semiconductor layer SCL2, which may be sequentially stacked on each other along the length L direction.

The light emitting element LD may be provided in a pillar shape extending along a direction. The light emitting element LD may have a first end portion EP1 and a second end portion EP2. The first semiconductor layer SCL1 may be adjacent to the first end portion EP1, and the second semiconductor layer SCL2 may be adjacent to the second end portion EP2.

The light emitting element LD may be a light emitting element manufactured in a pillar shape through an etching process, or the like. In this specification, the term “pillar shape” or “rod shape” may include a rod-like shape or bar-like shape, which may be long in the length L direction (i.e., its aspect ratio may be greater than 1), such as a cylinder or a polyprism, and the shape of its section is not particularly limited. For example, a length L of the light emitting element LD may be greater than a diameter D (or a width of a cross-section) of the light emitting element LD.

The light emitting element LD may have a size of nanometer scale to micrometer scale. For example, the light emitting element LD may have a diameter D (or width) in a range of nanometer scale to micrometer scale and/or a length L in a range of nanometer scale to micrometer scale. However, the size of the light emitting element LD is not limited thereto.

The first semiconductor layer SCL1 may be a first conductivity type semiconductor layer. The first semiconductor layer SCL1 may be disposed on the active layer ACL, and may include a semiconductor layer having a type different from a type of the second semiconductor layer SCL2. For example, the first semiconductor layer SCL1 may include a P-type semiconductor layer. In an example, the first semiconductor layer SCL1 may include at least one semiconductor material among InAlGaN, GaN, AlGaN, InGaN, AlN, and InN, and include a P-type semiconductor layer doped with a first conductivity type dopant such as Mg. However, the material constituting the first semiconductor layer SCL1 is not limited thereto. The first semiconductor layer SCL1 may be configured with various materials.

The active layer ACL may be disposed on the first semiconductor layer SCL1, and may be formed in a single-quantum well structure or a multi-quantum well structure. The position of the active layer ACL may be variously changed according to the kind of the light emitting element LD.

A clad layer doped with a conductive dopant may be formed on the top and/or the bottom of the active layer ACL. For example, the clad layer may be an AlGaN layer or an InAlGaN layer. In some embodiments, a material such as AlGaN or AlInGaN may be used to form the active layer ACL. The active layer ACL may be configured with various materials.

The second semiconductor layer SCL2 may be a second conductivity type semiconductor layer. The second semiconductor layer SCL2 may be disposed on the active layer ACL, and may include a semiconductor layer having a type different from the type of the first semiconductor layer SCL1. For example, the second semiconductor layer SCL2 may include an N-type semiconductor layer. For example, the second semiconductor layer SCL2 may include at least one semiconductor material among InAlGaN, GaN, AlGaN, InGaN, AlN, and InN, and include an N-type semiconductor layer doped with a second conductivity type dopant such as Si, Ge, Sn, or a combination thereof. However, the material constituting the second semiconductor layer SCL2 is not limited thereto. The second semiconductor layer SCL2 may be configured with various materials.

In case that a voltage which may be a threshold voltage or more is applied to both ends of the light emitting element LD, the light emitting element LD emits light as electron-hole pairs may be combined in the active layer ACL. The light emission of the light emitting element LD may be controlled by using such a principle, so that the light emitting element LD can be used as a light source for various light emitting devices, including a pixel of a display device.

The light emitting element LD may further include an insulative film INF provided on a surface thereof. The insulative film INF may be formed on the surface of the light emitting element LD to surround an outer circumferential surface of at least the active layer ACL. The insulative film INF may further surround areas of the first and second semiconductor layers SCL1 and SCL2. The insulative film INF may be formed as a single layer or a multi-layer. However, the disclosure is not limited thereto, and the insulative film INF may be configured with multiple layers.

The insulative film INF may expose both the end portions of the light emitting element LD, which have different polarities. For example, the insulative film INF may expose an end of each of the first and second semiconductor layers SCL1 and SCL2 respectively located at the first and second end portions EP1 and EP2. In another embodiment, the insulative film INF may expose side portions of the first and second semiconductor layers SCL1 and SCL2 adjacent to the first and second end portions EP1 and EP2 of the light emitting element LD, which have different polarities.

The insulative film INF may be configured as a single layer or a multi-layer, including at least one material among silicon oxide (SiOₓ), silicon nitride (SiNₓ), silicon oxynitride (SiOₓN_{y}), aluminum oxide (AlOₓ), and titanium oxide (TiOₓ), but the disclosure is not limited thereto. For example, in another embodiment, the insulative film INF may be omitted.

In accordance with an embodiment, in case that the insulative film INF is provided to cover the surface of the light emitting element LD, particularly, the outer circumferential surface of the active layer ACL, the electrical stability of the light emitting element LD can be ensured. Also, in case that the insulative film INF is provided on the surface of the light emitting element LD, a surface defect of the light emitting element LD may be minimized, thereby improving the lifetime and efficiency of the light emitting element LD. Even in case that light emitting elements LD are densely disposed, an unwanted short circuit can be prevented from occurring between the light emitting elements LD.

In accordance with an embodiment, the light emitting element LD may further include an additional component in addition to the first semiconductor layer SCL1, the active layer ACL, the second semiconductor layer SCL2, and/or the insulative film INF surrounding the same. For example, the light emitting element LD may further include a phosphor layer, an active layer, a semiconductor layer, and/or an electrode layer. A contact electrode layer may be further disposed at each of the first and second end portions EP1 and EP2 of the light emitting element LD.

FIG. 3 is a plan view schematically illustrating a display device in accordance with an embodiment of the disclosure.

The display device DD may be configured to emit light. Referring to FIG. 3, the display device DD may include pixels PXL including a substrate SUB and other components arranged on the substrate SUB. Although not shown in the drawing, the display device DD may further include a driving circuit (e.g., a scan driver and a data driver) for driving the pixels PXL, lines, and pads.

The display device DD may include a display area DA and a non-display area NDA. The non-display area NDA may mean an area except the display area DA. The non-display area NDA may surround at least a portion of the display area DA. In some embodiments, the display area DA may be designated as an active area, and the non-display area NDA may be designated as a non-active area.

The substrate SUB may constitute a base member of the display device DD. The substrate SUB may be a rigid or flexible substrate or film, but the disclosure is not limited to a specific example. For example, the substrate SUB may be a rigid substrate made of glass or tempered glass, a flexible substrate (or thin film) made of a plastic or metal material, or at least one insulating layer. The material and/or property of the substrate SUB is not particularly limited.

The display area DA may mean an area in which the pixels PXL may be disposed. The non-display area NDA may mean an area in which the pixels PXL may not be disposed. The driving circuit, the lines, and the pads, which may be connected to the pixels PXL of the display area DA, may be disposed in the non-display area NDA.

For example, the pixels PXL may be arranged according to a stripe arrangement structure, a PenTile® arrangement structure, or the like. However, the disclosure is not limited thereto, and various embodiments may be applied.

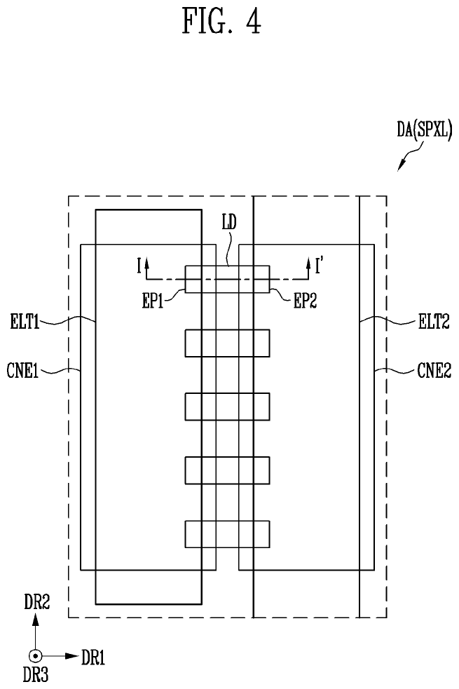

In accordance with an embodiment, the pixel PXL may include a first sub-pixel SPXL1, a second sub-pixel SPXL2, and a third sub-pixel SPXL3. Each of the first sub-pixel SPXL1, the second sub-pixel SPXL2, and the third sub-pixel SPXL3 may be a sub-pixel (see ‘SPXL’ shown in FIG. 4) for forming the pixel PXL. In some embodiments, the first sub-pixel SPXL1, the second sub-pixel SPXL2, and the third sub-pixel SPXL3 may constitute one pixel unit capable of emitting lights of various colors.

For example, each of the first sub-pixel SPXL1, the second sub-pixel SPXL2, and the third sub-pixel SPXL3 may emit light of a color. In an example, the first sub-pixel SPXL1 may be a red pixel emitting light of red (e.g., a first color), the second sub-pixel SPXL2 may be a green pixel emitting light of green (e.g., a second color), and the third sub-pixel SPXL3 may be a blue pixel emitting light of blue (e.g., a third color). However, the color, kind, and/or number of first, second, and third sub-pixels SPXL1, SPXL2, and SPXL3 constituting each pixel unit are not limited to a specific example.

FIG. 4 is a plan view schematically illustrating a sub-pixel in accordance with an embodiment of the disclosure. For example, a portion of the display area DA in which a sub-pixel SPXL may be disposed is schematically illustrated in FIG. 4. The sub-pixel SPXL shown in FIG. 4 may be one of the first to third sub-pixels SPXL1, SPXL2, and SPXL3. FIG. 4 is an embodiment, and illustrates an arrangement structure of light emitting elements LD connected in parallel between a first electrode ELT1 and a second electrode ELT2.

Referring to FIG. 4, the sub-pixel SPXL may include a first electrode ELT1, a second electrode ELT2, and light emitting elements LD disposed between the first electrode ELT1 and the second electrode ELT2. The sub-pixel SPXL may further include a first contact electrode CNE1 and a second contact electrode CNE2.

At least a portion of the light emitting element LD may be disposed between the first electrode ELT1 and the second electrode ELT2. The light emitting element LD may be aligned between the first electrode ELT1 and the second electrode ELT2.

The first electrode ELT1 and the second electrode ELT2 may be spaced apart from each other. For example, the first electrode ELT1 and the second electrode ELT2 may be spaced apart from each other along a first direction DR1 in each emission area (e.g., an emission area of each sub-pixel SPXL), and each of the first electrode ELT1 and the second electrode ELT2 may extend along a second direction DR2.

Each of the first electrode ELT1 and the second electrode ELT2 may have a pattern separated for each sub-pixel SPXL or have a pattern commonly connected in multiple sub-pixels SPXL. For example, the first electrode ELT1 may have a pattern independent for each sub-pixel SPXL, and be separated from first electrodes ELT1 of adjacent sub-pixels SPXL. The second electrode ELT2 may have a pattern independent for each sub-pixel SPXL, or be integrally connected to second electrodes ELT2 of adjacent sub-pixels SPXL.

In a process of forming sub-pixels SPXL, particularly, before light emitting elements LD may be completely aligned, first electrodes ELT1 of the sub-pixels SPXL may be connected to each other, and second electrodes ELT2 of the sub-pixels SPXL may be connected to each other. For example, before the light emitting elements LD may be completely aligned, the first electrodes ELT1 of the sub-pixels SPXL may be integrally or non-integrally connected to constitute a first alignment line, and the second electrodes ELT2 of the sub-pixels SPXL may be integrally or non-integrally connected to constitute a second alignment line.

The first alignment line and the second alignment line may be respectively supplied with a first alignment signal and a second alignment signal in a process of aligning the light emitting elements LD. The first and second alignment signals may have different wavelengths, potentials, and/or phases. Accordingly, an electric field may be formed between the first and second alignment lines, so that the light emitting elements LD can be aligned between the first and second alignment lines. After the light emitting elements LD may be completely aligned, the first electrodes ELT1 of the sub-pixels SPX may be separated from each other by cutting at least the first alignment line. Accordingly, the sub-pixels SPX can be individually driven.

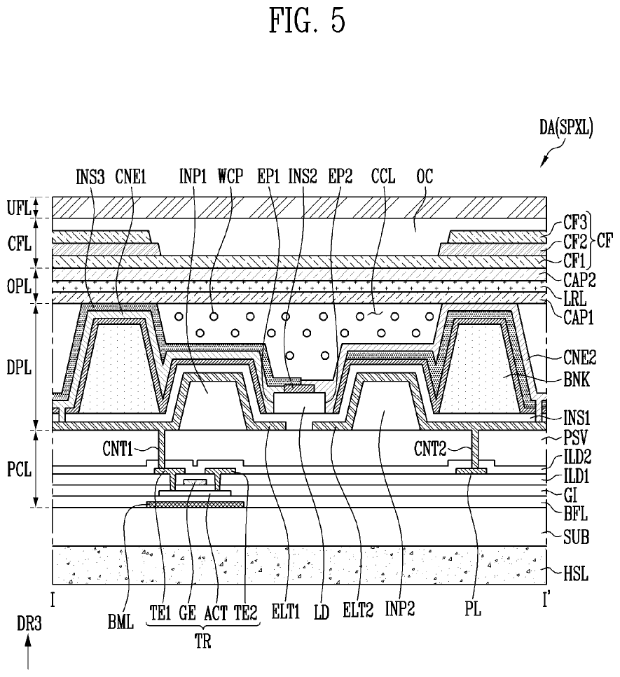

The first electrode ELT1 may be electrically connected to at least one circuit element (e.g., a transistor (see ‘TR’ shown in FIG. 5)). The first electrode ELT1 may provide an anode signal.

The second electrode ELT2 may be electrically connected to a power line (see ‘PL’ shown in FIG. 5). The second electrode ELT2 may provide a cathode signal.

Each of the first and second electrodes ELT1 and ELT2 may be configured as a single layer or a multi-layer. For example, each of the first and second electrodes ELT1 and ELT2 may include at least one reflective electrode layer including a reflective conductive material, and selectively further include at least one transparent electrode layer and/or at least one conductive capping layer.

The light emitting elements LD may be aligned between the first electrode ELT1 and the second electrode ELT2. For example, the light emitting elements LD may be aligned and/or connected in parallel between the first electrode ELT1 and the second electrode ELT2.

In an embodiment, each light emitting element LD may be aligned in the second direction DR2 between the first electrode ELT1 and the second electrode ELT2, to be electrically connected to the first and second electrodes ELT1 and ELT2. Although a case where all the light emitting elements LD may be uniformly aligned in the second direction DR2 is illustrated in FIG. 4, the disclosure is not limited thereto. For example, at least one of the light emitting elements LD may be arranged in an oblique direction inclined with respect to an extending direction of the first and second electrodes ELT1 and ELT2.

A first end portion EP1 of the light emitting element LD may be disposed adjacent to the first electrode ELT1, and a second end portion EP2 of the light emitting element LD may be disposed adjacent to the second electrode ELT2. The first end portion EP1 may or may not overlap the first electrode ELT1. The second end portion EP2 may or may not overlap the second electrode ELT2.

In an embodiment, the first end portion EP1 of each of the light emitting elements LD may be electrically connected to the first electrode ELT1 through the first contact electrode CNE1. In another embodiment, the first end portion EP1 of each of the light emitting elements LD may be connected directly to the first electrode ELT1. In still another embodiment, the first end portion EP1 of each of the light emitting elements LD may be electrically connected to only the first contact electrode CNE1, and may not be connected to the first electrode ELT1.

Similarly, the second end portion EP2 of each of the light emitting elements LD may be electrically connected to the second electrode ELT2 through the second contact electrode CNE2. In another embodiment, the second end portion EP2 of each of the light emitting elements LD may be connected directly to the second electrode ELT2. In still another embodiment, the second end portion EP2 of each of the light emitting elements LD may be electrically connected to only the second contact electrode CNE2, and may not be connected to the second electrode ELT2.

The light emitting elements LD may be provided (or prepared) in a form in which the light emitting elements LD may be dispersed in a solution, to be supplied to an emission area of each sub-pixel SPXL through an inkjet printing process, a slit coating process, or the like. In case that alignment signals are applied to first and second electrodes ELT1 and ELT2 (or first and second alignment lines) of the sub-pixels SPXL in a state in which light emitting elements LD may be supplied to each emission area, the light emitting elements LD may be aligned between the first and second electrodes ELT1 and ELT2. After the light emitting elements LD may be aligned, the solution may be removed through a drying process, or the like.

The first contact electrode CNE1 and the second contact electrode CNE2 may be respectively disposed over the first end portions EP1 and the second end portions EP2 of the light emitting elements LD.

The first contact electrode CNE1 may be disposed over the first end portions EP1 of the light emitting elements LD to be electrically connected to the first end portions EP1. In an embodiment, the first contact electrode CNE1 may be disposed on the first electrode ELT1 to be electrically connected to the first electrode ELT1. The first end portions EP1 of the light emitting elements LD may be connected to the first electrode ELT1 through the first contact electrode CNE1.

The second contact electrode CNE2 may be disposed over the second end portions EP2 of the light emitting elements LD to be electrically connected to the second end portions EP2. In an embodiment, the second contact electrode CNE2 may be disposed on the second electrode ELT2 to be electrically connected to the second electrode ELT2. The second end portions EP2 of the light emitting element LD may be connected to the second electrode ELT2 through the second contact electrode CNE2.

FIG. 5 is a schematic sectional view taken along line I-I′ shown in FIG. 4. FIG. 5 is a sectional view schematically illustrating the sub-pixel SPXL in accordance with the embodiment of the disclosure. A stacked structure of the sub-pixel SPXL is illustrated in FIG. 5.

Referring to FIG. 5, the sub-pixel SPXL may include a heat dissipation part HSL, a substrate SUB, a pixel circuit layer PCL, a display element layer DPL, an optical layer OPL, a color filter layer CFL, and an outer film layer UFL.

The heat dissipation part HSL may be disposed on a rear surface of the substrate SUB. The heat dissipation part HSL may be disposed adjacent to an outer surface of the display device DD. The heat dissipation part HSL may be disposed at an outer portion of the display device, to dissipate heat to the outside.

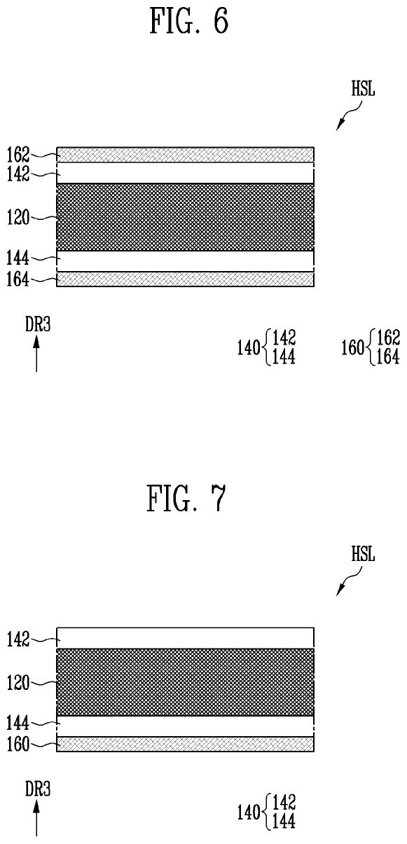

The heat dissipation part HSL may include a material having a high heat conductivity. For example, the heat dissipation part HSL may include a heat dissipation layer (see ‘120’ shown in FIG. 6) including graphite. In case that the heat dissipation layer 120 includes graphite, the heat dissipation layer 120 may have a high light absorptivity.

The heat dissipation part HSL will be described in detail later with reference to FIGS. 6 to 9.

In some embodiments, a cushion layer may be further disposed between the heat dissipation part HSL and the substrate SUB. The cushion layer may include an elastically deformable material, to reduce external impact applied to the display device DD.

The substrate SUB may form a base member of the sub-pixel SPXL. The substrate SUB may provide an area in which the pixel circuit layer PCL and the display element layer DPL may be disposed. The pixel circuit layer PCL and the display element layer DPL may be disposed on a surface of the substrate SUB, and the heat dissipation part HSL may be disposed on another surface of the substrate SUB. The substrate SUB may be disposed between the heat dissipation part HSL and the pixel circuit layer PCL.

The pixel circuit layer PCL may be disposed on the substrate SUB. The pixel circuit layer PCL may include a lower auxiliary electrode BML, a buffer layer BFL, a transistor TR, a gate insulating layer GI, a first interlayer insulating layer ILD1, a second interlayer insulating layer ILD2, a power line, a protective layer PSV, a first contact part CNT1, and a second contact part CNT2.

The lower auxiliary electrode BML may be disposed on the substrate SUB. The lower auxiliary electrode BML may serve as a path through which an electrical signal may be moved. In some embodiments, a portion of the lower auxiliary electrode BML may overlap the transistor TR in a plan view.

The buffer layer BFL may be disposed on the substrate SUB. The buffer layer BFL may cover the lower auxiliary electrode BML. The buffer layer BFL may prevent an impurity from being diffused from the outside. The buffer layer BFL may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

The transistor TR may be a thin film transistor. In accordance with an embodiment, the transistor TR may be a driving transistor. The transistor TR may be electrically connected to a light emitting element LD.

The transistor TR may include an active layer ACT, a first transistor electrode TE1, a second transistor electrode TE2, and a gate electrode GE.

The active pattern ACT may mean a semiconductor layer. The active layer ACT may be disposed on the buffer layer BFL. The active layer ACT may include at least one of poly-silicon, Low Temperature Polycrystalline Silicon (LTPS), amorphous silicon, and an oxide semiconductor.

The active pattern ACT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be disposed on the gate insulating layer GI. A position of the gate electrode GE may correspond to that of the channel region of the active pattern ACT. For example, the gate electrode GE may be disposed on the channel region of the active pattern ACT with the gate insulating layer GI interposed therebetween.

The gate insulating layer GI may be disposed over the active pattern ACT. The gate insulating layer GI may include an inorganic material. For example, the gate insulating layer GI may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

The first interlayer insulating layer ILD1 may be disposed over the gate electrode GE. The first interlayer insulating layer ILD1 may include an inorganic material. For example, the first interlayer insulating layer ILD1 may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

The first transistor electrode TE1 and the second transistor electrode TE2 may be disposed on the first interlayer insulating layer ILD1. The first transistor electrode TE1 may be in contact with the first contact region of the active pattern ACT while penetrating the gate insulating layer GI and the first interlayer insulating layer ILD1, and the second transistor electrode TE2 may be in contact with the second contact region of the active pattern ACT while penetrating the gate insulating layer GI and the first interlayer insulating layer ILD1. In an example, the first transistor electrode TE1 may be a drain electrode, and the second transistor electrode TE2 may be a source electrode. However, the disclosure is not limited thereto.

The first transistor electrode TE1 may be electrically connected to a first electrode ELT1 through the first contact part CNT1 formed in the protective layer PSV and the second interlayer insulating layer ILD2.

The second interlayer insulating layer ILD2 may be disposed over the first transistor electrode TE1, the second transistor electrode TE2 and the power line PL. The second interlayer insulating layer ILD2 may include an inorganic material. For example, the second interlayer insulating layer ILD2 may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

The power line PL may be disposed on the first interlayer insulating layer ILD1. The power line PL may be electrically connected to a second electrode ELT2 through the second contact part CNT2 formed in the protective layer PSV.

The protective layer PSV may be disposed on the second interlayer insulating layer ILD2. The protective layer PSV may include an inorganic material. For example, the protective layer PSV may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example. In some embodiments, the protective layer PSV may include an organic material. In some embodiments, the protective layer PSV may be a via layer.

The display element layer DPL may be disposed on the pixel circuit layer PCL. The display element layer DPL may include a first insulating pattern INP1, a second insulating pattern INP2, the first electrode ELT1, the second electrode ELT2, a first insulating layer INS1, a bank BNK, a light emitting element LD, a second insulating layer INS2, a first contact electrode CNE1, a third insulating layer INS3, and a second contact electrode CNE2.

The first insulating pattern INP1 and the second insulating pattern INP2 may be disposed on the protective layer PSV. The first insulating pattern INP1 and the second insulating pattern INP2 may have a shape protruding in a thickness direction of the substrate SUB (e.g., a third direction DR3). The first insulating pattern INP1 and the second insulating pattern INP2 may include an organic material and/or an inorganic material.

The first electrode ELT1 and the second electrode ELT2 may be disposed on the protective layer PSV. In accordance with an embodiment, at least a portion of the first electrode ELT1 may be arranged over the first insulating pattern INP1 and at least a portion of the second electrode ELT2 may be arranged over the second insulating pattern INP2, to each serve as a reflective partition wall.

The first electrode ELT1 may be electrically connected to the transistor TR through the first contact part CNT1. The second electrode ELT2 may be electrically connected to the power line PL through the second contact part CNT2.

The first electrode ELT1 may be electrically connected to the light emitting element LD. The first electrode ELT1 may be electrically connected to the first contact electrode CNE1 through a contact hole formed in the first insulating layer INS1. The first electrode ELT1 may apply an anode signal to the light emitting element LD.

The second electrode ELT2 may be electrically connected to the light emitting element LD. The second electrode ELT2 may be electrically connected to the second contact electrode CNE2 through a contact hole formed in the first insulating layer INS1. The second electrode ELT2 may apply a cathode signal (e.g., a ground signal) to the light emitting element LD.

The first electrode ELT1 and the second electrode ELT2 may include a conductive material. For example, the first electrode ELT1 and the second electrode ELT2 may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the disclosure is not limited to the above-described example.

The first insulating layer INS1 may be disposed on the protective layer PSV. The first insulating layer INS may cover the first electrode ELT1 and the second electrode ELT2. The first insulating layer INS1 may stabilize connection between electrode components, and reduce external influence. The first insulating layer INS1 may include at least one of silicon oxide (SiOₓ), silicon nitride (SiNₓ), silicon oxynitride (SiOₓN_{y}), aluminum oxide (AlOₓ), and titanium oxide (TiOₓ).

The bank BNK may be disposed on the first insulating layer INS1. The bank BNK may have a shape protruding in the thickness direction of the substrate (e.g., the third direction DR3). The bank BNK may include an organic material and/or an inorganic material. The bank BNK may form a space in which a solvent for providing the light emitting element LD can be accommodated.

The light emitting element LD may be disposed on the first insulating layer INS1. The light emitting element LD may emit light, based on an electrical signal provided from the first contact electrode CNE1 and the second contact electrode CNE2.

In accordance with an embodiment, the light emitting element LD may emit light of a third color (e.g., blue). A color conversion layer CCL and the color filter layer CFL may be provided in sub-pixels SPXL, so that a full-color image can be displayed. However, the disclosure is not necessarily limited thereto, and light emitting elements LD emitting lights of different colors may be provided in each of the sub-pixels SPXL.

A portion of the second insulating layer INS2 may be disposed on the light emitting element LD. The second insulating layer INS2 may cover an active layer ACL of the light emitting element LD. In some embodiments, the second insulating layer INS2 may include an organic material or an inorganic material.

In accordance with an embodiment, the second insulating layer INS2 may expose at least a portion of the light emitting element LD. For example, the second insulating layer INS2 may not cover a first end portion EP1 and a second end portion EP2 of the light emitting element LD. Accordingly, the first end portion EP1 and the second end portion EP2 of the light emitting element LD may be exposed, and be electrically connected respectively to the first contact electrode CNE1 and the second contact electrode CNE2.

In accordance with an embodiment, a portion of the second insulating layer INS2 may be disposed on the first insulating layer INS1. For example, a portion of the second insulating layer INS2 may be disposed on the first insulating pattern INP1, the second insulating pattern INP2, and the bank BNK on the first insulating layer INS1. The second insulating layer INS2 may also expose at least a portion of the light emitting element LD.

The first contact electrode CNE1 and the second contact electrode CNE2 may be disposed on the first insulating layer INS1. In accordance with an embodiment, the first contact electrode CNE1 may be disposed on the first insulating layer INS1 and the second insulating layer INS2, and the second contact electrode CNE2 may be disposed on the first insulating layer INS1, the second insulating layer INS2, and the third insulating layer INS3.

The first contact electrodes CNE1 may electrically connect the first electrode ELT1 and the light emitting element LD to each other, and the second contact electrode CNE2 may electrically connect the second electrode ELT2 and the light emitting element LD to each other.

The first contact electrode CNE1 and the second contact electrode CNE2 may include a conductive material. For example, the first contact electrode CNE1 and the second contact electrode CNE2 may include a transparent conductive material including Indium Tin Oxide (ITO), Indium Zinc Oxide (IZO), Indium Tin Zinc Oxide (ITZO), or a combination thereof, but the disclosure is not limited thereto.

The third insulating layer INS3 may be disposed over the first contact electrode CNE1. The third insulating layer INS3 may prevent a short circuit between the first contact electrode CNE1 and the second contact electrode CNE2.

The third insulating layer INS3 may include an inorganic material. For example, the third insulating layer INS3 may include at least one of silicon oxide (SiOₓ), silicon nitride (SiNₓ), silicon oxynitride (SiOₓN_{y}), aluminum oxide (AlOₓ), and titanium oxide (TiOₓ). However, the disclosure is not necessarily limited to the above-described example.

In accordance with an embodiment, the display element layer DPL may further include a color conversion layer CCL. However, the disclosure is not necessarily limited to the above-described example. In some embodiments, the color conversion layer CCL may be separately provided in a layer different from the display element layer DPL.

The color conversion layer CCL may allow a wavelength of light provided from the light emitting element LD to be changed or transmitted therethrough.

For example, in case that the sub-pixel SPXL is a first sub-pixel SPXL1 emitting light of a first color (e.g., red), a wavelength conversion pattern WCP of the color conversion layer CCL may include first color conversion particles for converting light of the third color into light of the first color. The first color conversion particles may include a first quantum dot for converting light of blue into light of red. The first quantum dot may absorb blue light and emit red light by shifting a wavelength of the blue light according to energy transition.

In another example, in case that the sub-pixel SPXL is a second sub-pixel SPXL2 emitting light of a second color (e.g., green), the wavelength conversion pattern WCP of the color conversion layer CCL may include second color conversion particles for converting light of the third color into light of the second color. The second color conversion particles may include a second quantum dot for converting light of blue into light of green. The second quantum dot may absorb blue light and emit green light by shifting a wavelength of the blue light according to energy transition.

The first quantum dot and the second quantum dot may have shape such as a spherical shape, a pyramid shape, a multi-arm shape, a cubic nano particle, a nano wire, a nano fabric, or a nano plate particle. However, the disclosure is not necessarily limited thereto, and the shape of the first quantum dot and the second quantum dot may be variously changed.

In still another example, in case that the sub-pixel SPXL is a third sub-pixel SPXL3 emitting light of the third color (e.g., blue), the color conversion layer CCL may include a light transmission pattern (not shown). The light transmission pattern may be used to efficiently use light emitted from the light emitting element LD, and may include light scattering particles dispersed in a matrix material such as base resin. For example, the light transmission pattern may include light scattering particles such as silica, but the material constituting the light scattering particles is not limited thereto.

The optical layer OPL may be disposed on the display element layer DPL. In accordance with an embodiment, the optical layer OPL may include a first capping layer CAP1, a low refractive layer LRL, and a second capping layer CAP2.

The first capping layer CAP1 may encapsulate (or cover) the color conversion layer CCL. The first capping layer CAP1 may be disposed between the low refractive layer LRL and the display element layer DPL. The first capping layer CAP1 may be provided throughout the sub-pixels SPXL. The first capping layer CAP1 may prevent the color conversion layer CCL from being damaged or contaminated due to infiltration of an impurity such as moisture or air from the outside.

In accordance with an embodiment, the first capping layer CAP1 may include at least one of silicon nitride (SiNₓ), silicon oxide (SiOₓ), silicon oxynitride (SiOₓN_{y}), and aluminum oxide (AlOₓ).

The low refractive layer LRL may be disposed between the first capping layer CAP1 and the second capping layer CAP2. The low refractive layer LRL may be disposed between the color conversion layer CCL and the color filter layer CFL. The low refractive layer LRL may be provided throughout the sub-pixels SPXL.

The low refractive layer LRL may recycle light provided from the color conversion layer CCL, thereby improving light efficiency. To this end, the low refractive layer LRL may have a refractive index lower than a refractive index of the color conversion layer CCL.

In accordance with an embodiment, the low refractive layer LRL may include a base resin and hollow particles dispersed in the base resin. The hollow particle may include a hollow silica particle. In other embodiments, the hollow particle may be a pore formed by porogen, but the disclosure is not necessarily limited thereto. Also, the low refractive layer LRL may include at least one of a zinc oxide (ZnO) particle, a titanium dioxide (TiO₂) particle, and a nano silicate particle, but the disclosure is not necessarily limited thereto.

The second capping layer CAP2 may be disposed on the low refractive layer LRL. The second capping layer CAP2 may be disposed between the color filter layer CFL and the low refractive layer LRL. The second capping layer CAP2 may be provided throughout the sub-pixels SPXL. The second capping layer CAP2 may prevent the low refractive layer LRL from being damaged or contaminated due to infiltration of an impurity such as moisture or air from the outside.

In accordance with an embodiment, the second capping layer CAP2 may include at least one of silicon nitride (SiNₓ), silicon oxide (SiOₓ), silicon oxynitride (SiOₓN_{y}), and aluminum oxide (AlOₓ).

The color filter layer CFL may be disposed on the second capping layer CAP2. The color filter layer CFL may be provided throughout the sub-pixels SPXL. The color filter layer CFL may include color filters CF1, CF2, and CF3, and an overcoat layer OC.

The color filters CF1, CF2, and CF3 may be provided on the second capping layer CAP2.

In accordance with an embodiment, in case that the sub-pixel SPXL is the first sub-pixel SPXL1 emitting light of the first color, an emission area in which light of the light emitting element LD may be emitted may overlap a first color filter CF1 and may not overlap a second color filter CF2 and a third color filter CF3, in a plan view. An embodiment in which the sub-pixel SPXL may be the first sub-pixel SPXL1 is illustrated in FIG. 5.

In accordance with an embodiment, in case that the sub-pixel SPXL is the second sub-pixel SPXL2 emitting light of the second color, the emission area in which light of the light emitting element LD is emitted may overlap the second color filter CF2 and may not overlap the first color filter CF1 and the third color filter CF3, in a plan view.

In accordance with an embodiment, in case that the sub-pixel SPXL is the third sub-pixel SPXL3 emitting light of the third color, the emission area in which light of the light emitting element LD is emitted may overlap the third color filter CF3 and may not overlap the first color filter CF1 and the second color filter CF2, in a plan view.

The first color filter CF1 may allow light of the first color to be transmitted therethrough, and may allow light of the second color and light of the third color not to be transmitted therethrough. In an example, the first color filter CF1 may include a colorant of the first color.

The second color filter CF2 may allow light of the second color to be transmitted therethrough, and may allow light of the first color and light of the third color not to be transmitted therethrough. In an example, the second color filter CF2 may include a colorant of the second color.

The third color filter CF3 may allow light of the third color to be transmitted therethrough, and may allow light of the first color and light of the second color not to be transmitted therethrough. In an example, the third color filter CF3 may include a colorant of the third color.

The overcoat layer OC may be disposed over the color filters CF. The overcoat layer OC may be provided throughout the sub-pixels SPXL. The overcoat layer OC may cover a lower member including the color filters CF. The overcoat layer OC may prevent moisture or air from infiltrating into the above-described lower member. Also, the overcoat layer OC may protect the above-described lower member from a foreign matter such as dust.

In accordance with an embodiment, the overcoat layer OC may include an organic material such as acryl resin, epoxy resin, phenolic resin, polyamide resin, polyimide resin, unsaturated polyester resin, poly-phenylene ether resin, poly-phenylene sulfide resin, benzocyclobutene (BCB), or a combination thereof. However, the disclosure is not necessarily limited to the above-described example.

The outer film layer UFL may be disposed on the color filter layer CFL. The outer film layer UFL may be disposed at an outer portion of the display device DD, to reduce external influence. The outer film layer UFL may be provided throughout the sub-pixels SPXL. In some embodiments, the outer film layer UFL may include at least one of a polyethylenephthalate (PET) film, a low reflective film, a polarizing film, and a transmittance controllable film, but the disclosure is not necessarily limited thereto.

For example, the outer film layer UFL may include an anti-reflective (AR) coating for decreasing reflexibility of light. The AR coating may mean a component formed by coating a material having an anti-reflection function on one surface of a specific component. The coated material may have a low reflexibility.

FIGS. 6 to 9 are schematic sectional views illustrating a heat dissipation part in accordance with an embodiment of the disclosure.

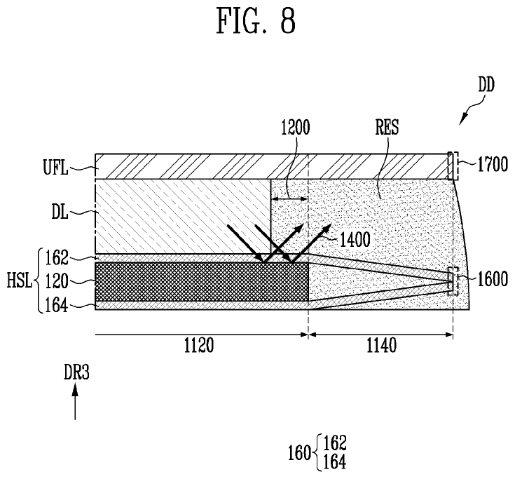

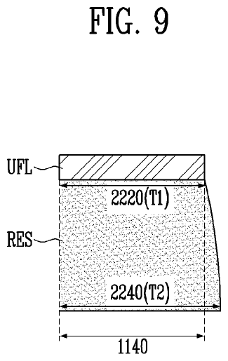

FIG. 6 is a sectional view schematically illustrating a heat dissipation part HSL in accordance with an embodiment of the disclosure. FIG. 7 is a sectional view schematically illustrating a heat dissipation part HSL in accordance with another embodiment of the disclosure. FIG. 8 is a schematic sectional view illustrating a heat dissipation part HSL and a resin part RES. FIG. 9 may be a sectional view illustrating a thickness of the resin part RES.

First, detailed sectional structures of heat dissipation parts in accordance with embodiments of the disclosure will be described with reference to FIGS. 6 and 7.

First, referring to FIG. 6, the heat dissipation part HSL in accordance with an embodiment of the disclosure may include a heat dissipation layer 120, an adhesive layer 140, and a cover layer 160. For example, the heat dissipation layer 120, the adhesive layer 140, and the cover layer 160 may be stacked along the thickness direction of the substrate SUB (e.g., the third direction DR3).

The heat dissipation layer 120 may include a material having a high heat conductivity so as to reduce a heat generation issue. For example, the heat dissipation layer 120 may include graphite.

The heat dissipation layer 120 may be adjacent to the cover layer 160. The heat dissipation layer 120 may be sealed by the cover layer 160. The heat dissipation layer 120 may be disposed between a first cover layer 162 and a second cover layer 164. The heat dissipation layer 120 may be disposed between a first adhesive layer 142 and a second adhesive layer 144. A surface of the heat dissipation layer 120 may be coupled to the first cover layer 162 through the first adhesive layer 142. Another surface of the heat dissipation layer 120 may be coupled to the second cover layer 164 through the second adhesive layer 144.

The adhesive layer 140 may connect (or couple) the heat dissipation layer 120 and the cover layer 160 to each other. The adhesive layer 140 may include the first adhesive layer 142 and the second adhesive layer 144. In accordance with an embodiment, the first adhesive layer 142 may couple the surface of the heat dissipation layer 120 and the first cover layer 162 to each other. The second adhesive layer 144 may couple another surface of the heat dissipation layer 120 and the second cover layer 164 to each other.

The adhesive layer 140 may include an adhesive material. For example, the adhesive layer 140 may include a Pressure Sensitive Adhesive (PSA). However, the disclosure is not necessarily limited to the above-described example. For example, the adhesive layer 140 may include a polyurethane-based adhesive, and the like.

The cover layer 160 may include the first cover layer 162 and the second cover layer 164. The first cover layer 162 and the second cover layer 164 may respectively seal both the surfaces of the heat dissipation layer 120. For example, the first cover layer 162 may cover a surface of the heat dissipation layer 120, and the second cover layer 164 may cover another surface of the heat dissipation layer 120.

The first cover layer 162 may be coupled to the heat dissipation layer 120 by the first adhesive layer 142. The second cover layer 164 may be coupled to the heat dissipation layer 120 by the second adhesive layer 144.

The cover layer 160 may be adjacent to one surface of the heat dissipation layer 120. The cover layer 160 may be disposed at an outer surface of the heat dissipation part HSL. For example, the first cover layer 162 may be disposed at one outer surface of the heat dissipation part HSL. The second cover layer 164 may be disposed at another outer surface of the heat dissipation part HSL.

In case that the heat dissipation layer 120 includes graphite, the cover layer 160 may prevent diffusion of particles or the like of the graphite. For example, the first cover layer 162 may seal a surface of the heat dissipation layer 120 and the second cover layer 164 may seal another surface of the heat dissipation layer 120, thereby preventing diffusion of particles of the graphite.

The cover layer 160 may include a material suitable for sealing the heat dissipation layer 120. For example, the cover layer 160 may include polyethylene terephthalate (PET). However, the disclosure is not necessarily limited to the above-described example.

The heat dissipation part HSL in accordance with another embodiment of the disclosure will be described with reference to FIG. 7. The heat dissipation part HSL in accordance with an embodiment of the disclosure may be different from the heat dissipation part HSL in accordance with a different embodiment of the disclosure, in that the cover layer 160 may not be disposed on a surface of the heat dissipation layer 120.

Referring to FIG. 7, the cover layer 160 may be disposed on a surface of the heat dissipation layer 120. In accordance with this embodiment, the cover layer 160 may not be disposed on another surface of the heat dissipation layer 120. For example, a surface of the heat dissipation layer 120 may be exposed by the cover layer 160.

A surface of the heat dissipation layer 120, on which the cover layer 160 may not be disposed, may be disposed adjacent to the substrate SUB. The first adhesive layer 142 may couple the substrate SUB and the heat dissipation layer 120 to each other. For example, the cover layer 160 may be disposed adjacent to an outer surface of the heat dissipation part HSL.

In accordance with an embodiment, an outer portion of the display device DD may be sealed by a resin part (see ‘RES’ shown in FIG. 8), and accordingly, the diffusion of particles of the graphite can be effectively reduced, even in case that the cover layer 160 is not disposed on both the surfaces of the heat dissipation layer 120. Thus, in accordance with this embodiment, process cost can be reduced, and process steps can be simplified.

Hereinafter, based on a structure of a resin part RES and a heat dissipation part HSL, a display device DD in accordance with an embodiment of the disclosure will be described with reference to FIGS. 8 and 9.

FIGS. 8 and 9 are schematic sectional views of a display device in accordance with an embodiment of the disclosure.

First, a structure of the display device DD including the resin part RES and the heat dissipation part HSL in accordance with an embodiment of the disclosure will be described with reference to FIG. 8. FIG. 8 may be a sectional view illustrating the outer film layer UFL, the resin part RES, and the heat dissipation part HSL.

FIG. 8 may be a sectional view schematically illustrating a side of the display device DD. For example, the display device DD may include multiple sides. A sectional structure of one of the sides may be illustrated in FIG. 8.

In FIG. 8, a substrate SUB, a pixel circuit layer PCL, a display element layer DPL, an optical layer OPL, and a color filter layer CFL are inclusively illustrated as a display layer DL. In accordance with an embodiment, an area in which the display layer DL may be disposed may correspond to the above-described display area DA. For example, the display layer DL may overlap the display area DA in a plan view.

In FIG. 8, an embodiment in which a cover layer 160 may be disposed on both surfaces of a heat dissipation layer 120 is illustrated.

The display device DD may include a first area 1120 and a second area 1140. The first area 1120 may be an area in which the heat dissipation layer 120 may be disposed. The first area 1120 may be an area overlapping the heat dissipation layer 120 in a plan view. The second area 1140 may be an area in which the heat dissipation layer 120 may not be disposed. The second area 1140 may be an area not overlapping the heat dissipation layer 120 in a plan view.

The outer film layer UFL may overlap the heat dissipation layer 120, the cover layer 160, and the display layer DL in the first area 1120, in a plan view. The outer film layer UFL may overlap the resin part RES and the cover layer 160 in the second area 1140, in a plan view. In some embodiments, the outer film layer UFL may not overlap a portion of the resin part RES in a plan view. The outer film layer UFL may further overlap a portion of the resin part RES in the first area 1120, in a plan view.

The heat dissipation part HSL may be adjacent to the resin part RES. The heat dissipation part HSL may be disposed on a surface of the display layer DL. For example, a first cover layer 162 may be disposed between the display layer DL and the heat dissipation layer 120. The heat dissipation layer 120 may be disposed between the display layer DL and a second cover layer 164.

The heat dissipation layer 120 may overlap the display layer DL and the outer film layer UFL in the first area 1120, in a plan view. The heat dissipation layer 120 may not be disposed in the second area 1140.

The heat dissipation layer 120 may extend by the same length as the display layer DL or extend farther than the display layer DL. The heat dissipation layer 120 may extend farther by a heat dissipation extension length 1200 than the display layer DL. For example, in a plan view, the display layer DL may overlap the heat dissipation layer 120, but at least a portion of the heat dissipation layer 120 may not overlap the display layer DL. In some embodiments, an area of the heat dissipation layer 120, which may not overlap the display layer DL, may overlap the resin part RES. For example, the heat dissipation layer 120 may overlap the resin part RES in a portion of the first area 1120, in a plan view.

In accordance with an embodiment of the disclosure, the heat dissipation performance of the heat dissipation layer 120 with respect to the display layer DL can be further improved. In accordance with the disclosure, the heat dissipation layer 120 entirely covers areas of the display layer DL, so that heat radiated from the display layer DL can be effectively absorbed. Accordingly, heat generation risk of the display device DD can be reduced. For example, in accordance with an embodiment, the display layer DL may not include any area not overlapping the heat dissipation layer 120.

A light leakage phenomenon of the display device DD can be effectively prevented. For example, lights emitted from the display layer DL may be reflected by layers and diffused into an outer portion along a lower light path 1400. The lights may be totally reflected by the heat dissipation part HSL and diffused into the outer portion. The lights diffused into the outer portion may be absorbed or blocked by the resin part RES not to be viewed at the outside. For example, the resin part RES may seal an outer surface in a structure in which the heat dissipation layer 120 covers the display layer DL, thereby preventing the light leakage phenomenon.

The heat dissipation layer 120 may be covered by the resin part RES. A side surface of the heat dissipation layer 120 may be sealed by the resin part RES. For example, a portion of the heat dissipation layer 120 may be exposed by the first cover layer 162 and the second cover layer 164, which may be disposed in the second area 1140. However, the exposed portion of the heat dissipation layer 120 may be sealed by the resin part RES. Accordingly, in case that the heat dissipation layer 120 includes graphite, particles can be effectively sealed. In accordance with an embodiment of the disclosure, diffusion of particles can be prevented even in case that only one surface of the heat dissipation layer 120 is sealed (FIG. 7).

At least a portion of the cover layer 160 may be disposed in the second area 1140. The cover layer 160 may overlap the resin part RES and the outer film layer UFL in a plan view.

The cover layer 160 may include a cut surface 1600. For example, at least a portion of the cover layer 160 may be cut through a process during a manufacturing process.

The cut surface 1600 of the cover layer 160 may correspond to a film cut surface 1700 of the outer film layer UFL. The cut surface 1600 and the film cut surface 1700 may be disposed at positions corresponding to (or overlapping) each other. The cut surface 1600 and the film cut surface 1700 may be provided in the same cutting process.

In some embodiments, the cut surface 1600 may be designated as a first cut surface, and the film cut surface 1700 may be designated as a second cut surface.

In some embodiments, at the cut surface 1600, the first cover layer 162 and the second cover layer 164 may be spaced apart from each other. The heat dissipation layer 120 may be exposed. However, during a process of providing the resin part RES, the resin part RES may be input between the first cover layer 162 and the second cover layer 164, so that the heat dissipation layer 120 can be sealed.

The resin part RES may be disposed at a side of the display device DD. For example, the resin part RES may be disposed along an outer surface of the display device DD.

The resin part RES may cover (or seal) the heat dissipation part HSL. The resin part RES may seal the heat dissipation layer 120. In accordance with an embodiment, the resin part RES may be a member including resin. For example, the resin part RES may include an ordinary organic compound. The resin part RES may include various resins including polymer and the like, but the disclosure is not necessarily limited to a specific example. In accordance with an embodiment, the resin part RES may appropriately include resin having a property and a color.

The resin part RES may cover (or seal) a side surface of the display layer DL. The resin part RES may seal light emitted from the display layer DL, thereby preventing the light leakage phenomenon.

The resin part RES may overlap the cover layer 160 and the outer film layer UFL in the second area 1140, in a plan view. The resin part RES may be disposed between the first cover layer 162 and the second cover layer 164 in the second area 1140.

In some embodiments, a portion of the resin part RES may overlap the heat dissipation layer 120 in a plan view. For example, in case that the heat dissipation layer 120 extends farther by the heat dissipation extension length 1200 than the display layer DL, the resin part RES may overlap by the heat dissipation extension length 1200 with the heat dissipation layer 120 in a plan view. The resin part RES may overlap an area in which the heat dissipation extension length 1200 may be defined, in a plan view.

In some embodiments, a portion of the resin part RES may protrude at an outer portion of the display device DD. A sectional profile of the resin part RES will be described in detail later with reference to FIG. 9. FIG. 9 may be a sectional view illustrating a length relationship of the resin part RES. FIG. 9 may illustrate the second area 1140 and an area partially extending from the second area 1140. In FIG. 9, for convenience of description, illustration of the cover layer 160 is omitted.

Referring to FIG. 9, a portion of the resin part RES may not overlap the outer film layer UFL. For example, in a plan view, the resin part RES may protrude at least partially from the second area 1140 while overlapping the outer film layer UFL in the second area 1140.

The resin part RES may be adjacent to another component or have a sufficient thickness in an area adjacent to an outer portion. For example, the resin part RES may include a film adjacent surface 2220 and an outer lower surface 2240. The film adjacent surface 2220 and the outer lower surface 2240 may have a sufficient thickness. The film adjacent surface 2220 may be a portion of the resin part RES, and may be a surface adjacent to the outer film layer UFL. The outer lower surface 2240 may be a portion of the resin part RES, and may be a surface adjacent to a lower surface of the display device DD. The outer lower surface 2240 may be a portion of the resin part RES, and may be a surface disposed at another side of the film adjacent surface 2220.

The film adjacent surface 2220 may have a first thickness T1 from a division point of the first area 1120 and the second area 1140, with respect to an extending direction of the outer film layer UFL. The outer lower surface 2240 may have a second thickness T2 from the division point of the first area 1120 and the second area 1140, with respect to the extending direction of the outer film layer UFL.

The first thickness T1 may correspond to a length of the outer film layer UFL in the second area 1140. For example, the first thickness T1 may be substantially equal to the length of the outer film layer UFL in the second area 1140.

In accordance with an embodiment, the second thickness T2 may be greater than the first thickness T1.

In accordance with an embodiment, the first thickness T1 may be smaller than an average thickness with respect to an extending direction of the outer film layer UFL. The second thickness T2 may be greater than an average thickness with respect to the extending direction of the resin part RES to the outer film layer UFL.

The average thickness may be an average thickness of the resin part RES, and may be an average value of thicknesses from the division point of the first area 1120 and the second area 1140, with respect to the extending direction of the outer film layer UFL.

At least one of the first thickness T1 and the second thickness T2 may be greater than 0. The first thickness T1 and the second thickness T2 may be within a difference from a length of the second area 1140. The first thickness T1 and the second thickness T2 may be equal to or greater than the length of the second area 1140.

In accordance with an embodiment of the disclosure, the resin part RES may have a sufficient thickness (e.g., the first thickness T1, the second thickness T2, and the like) in the extending direction of the outer film layer UFL, so that the light leakage phenomenon of the display device DD can be effectively prevented.

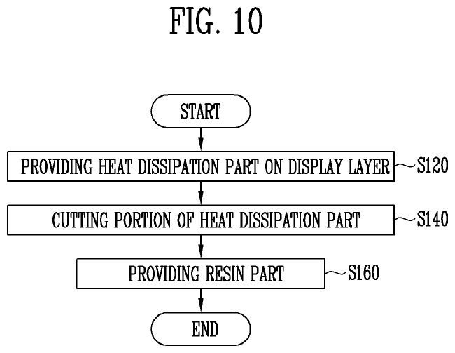

Hereinafter, a manufacturing method for the display device DD in accordance with an embodiment of the disclosure will be described with reference to FIGS. 10 to 16. In FIGS. 10 to 16, descriptions of portions overlapping those described above will be simplified or omitted.

FIG. 10 is a flowchart schematically illustrating a manufacturing method for the display device in accordance with an embodiment of the disclosure.

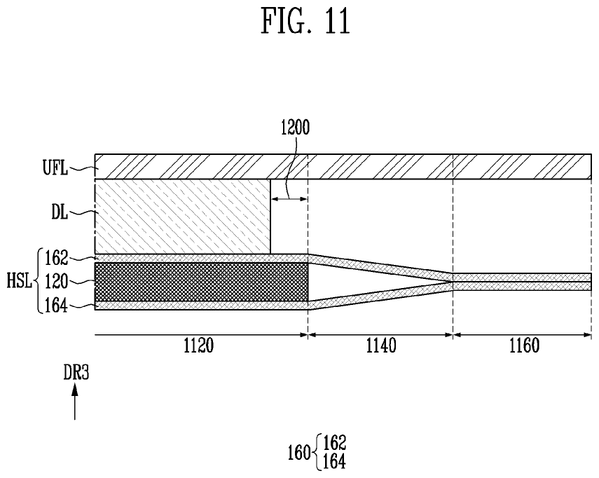

FIGS. 11 to 13, 15, and 16 are schematic process sectional views illustrating a manufacturing method for the display device in accordance with an embodiment of the disclosure.

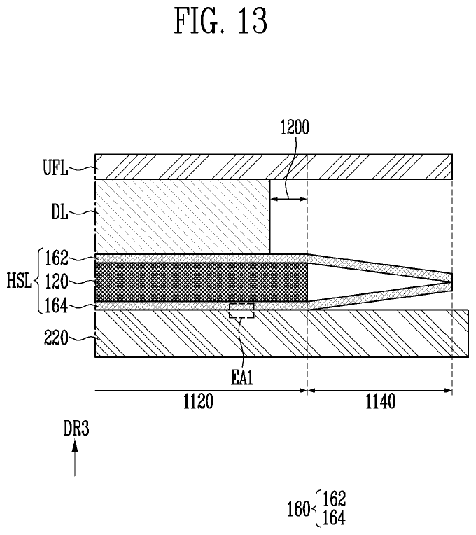

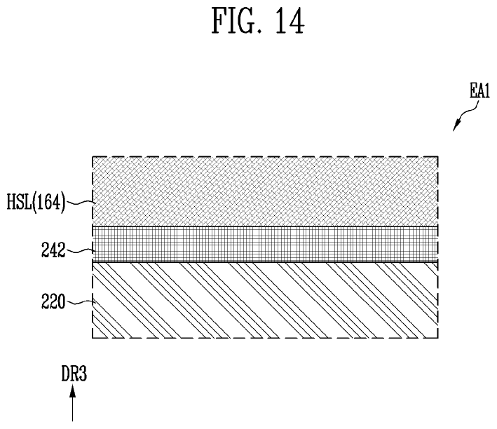

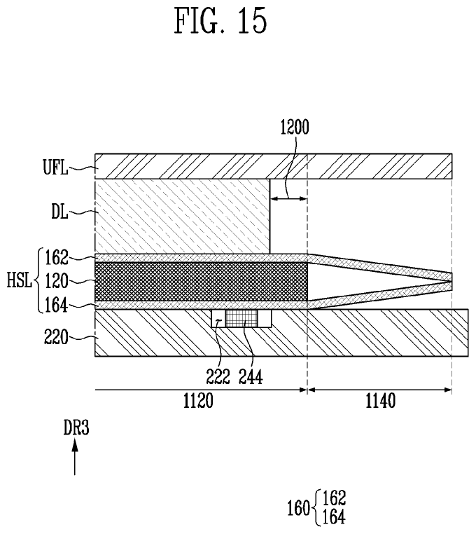

FIG. 14 is a schematic enlarged view of area EA1 shown in FIG. 13.

Referring to FIG. 10, the manufacturing method for the display device DD in accordance with the embodiment of the disclosure may include step S120 of providing a heat dissipation part on a display layer, step S140 of cutting a portion of the heat dissipation part, and step S160 of providing a resin part.

Referring to FIGS. 10 and 11, in the step S120 of providing the heat dissipation part on the display layer, a display layer DL may be provided, and a heat dissipation part HSL may be provided (or disposed) on a surface (e.g., a rear surface) of the display layer DL. An outer film layer UFL may be provided (or disposed) on a surface of the display layer DL.

In order to provide the display layer DL, a pixel circuit layer PCL and a display element layer DPL may be disposed (or provided) on a substrate SUB. In an example, individual components of the pixel circuit layer PCL may be formed by patterning a conductive layer, an inorganic material, an organic material, or the like through a process using an ordinary mask. Light emitting elements LD may be disposed after the circuit pixel layer PCL may be provided. In accordance with an embodiment, the light emitting elements LD may be disposed through an inkjet process.

In this step, an order in which the outer film layer UFL and the heat dissipation part HSL may be disposed on both surfaces of the display layer DL is not limited to a specific example.

In accordance with an embodiment, the heat dissipation part HSL may be disposed such that a first cover layer 162 may be adjacent to the display layer DL and a second cover layer 164 may be spaced apart from the display layer D. In accordance with an embodiment, the display layer DL may be coupled to the first cover layer 162 by an adhesive layer. In accordance with an embodiment, the first cover layer 162 may be omitted as described above.

In this step, a first area 1120 overlapping a heat dissipation layer 120 may be defined. As described above, the heat dissipation layer 120 may have a shape extending farther by a heat dissipation extension length 1200 than the display layer DL. However, in some embodiments, the heat dissipation layer 120 and the display layer DL may extend by substantially a same length, so that a non-overlapping area corresponding to the heat dissipation extension length 1200 may not be provided.

In this step, a second area 1140 may be defined. The second area 1140 may be an area in which the heat dissipation layer 120 may not be disposed, and may be an area adjacent to the first area 1120. The second area 1140 may be disposed between the first area 1120 and a third area 1160.

In this step, the third area 1160 may be defined. The third area 1160 may be an area in which the heat dissipation layer 120 may not be disposed, and may be an area removed in case that a subsequent process is performed. The third area 1160 may be disposed at an outermost portion during a manufacturing process of the display device DD. In some embodiments, the third area 1160 may be adjacent to the second area 1140. The third area 1160 may overlap the outer film layer UFL in a plan view.

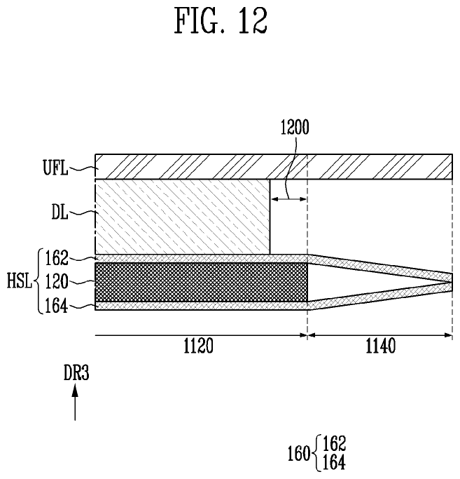

Referring to FIGS. 10 and 12, in the step S140 of cutting the portion of the heat dissipation part, a portion of a cover layer 160 may be cut.

In this step, a portion of the cover layer 160 of the heat dissipation part HSL may be cut, and a portion of the outer film layer UFL may be cut. In accordance with an embodiment, the cover layer 160 and the outer film layer UFL may be cut through the same process. Components corresponding to the third area 1160 may be removed. For example, the portion of the outer film layer UFL and the portion of the cover layer 160, which may be removed in this step, may overlap the third area 1160 in a plan view.

In some embodiments, the first cover layer 162 and the second cover layer 164 may be spaced apart from each other, so that the heat dissipation layer 120 may be exposed.

The cutting process performed in this step may use a cutting method. For example, the cutting process performed in this step may use a laser cutting method.

Referring to FIGS. 10 and 13 to 16, in the step S160 of providing the resin part, a resin part RES may be provided (or disposed) at a side of the display device DD.

In accordance with an embodiment, a support plate 220 may be disposed on one surface of the heat dissipation part HSL, and the resin part RES may be provided. However, in some embodiments, after the resin part RES may be disposed, the support plate 220 may be disposed. Hereinafter, an embodiment in which the support plate 220 may be disposed earlier than a time at which the resin part RES may be provided will be described.

The support plate 220 may be disposed on one surface of the heat dissipation part HSL, which may not be adjacent to the display layer DL. The support plate 220 may overlap the heat dissipation part HSL and the outer film layer UFL in a plan view. The support plate 220 may extend farther than the outer film layer UFL in a plan view.

The support plate 220 may have a strength suitable for supporting the position of the resin part RES. The support plate 220 may specify the position of the resin part RES. The support plate 220 may be a dam structure for supporting the resin part RES.

In accordance with an embodiment, the support plate 220 may be attached to the heat dissipation part HSL by a double-sided adhesive part 242 (see FIG. 14). The double-sided adhesive part 242 may include various adhesive materials, and connect a component disposed at a surface of the double-sided adhesive part 242 and a component disposed at another surface of the double-side adhesive part 242 to each other. The support plate 220 may be connected to the second cover layer 164 by the double-sided adhesive part 242. In case that the double-sided adhesive part 242 is used, the shape of the support plate 220 can be simplified.

The method in which the support plate 220 may be connected to the heat dissipation part HSL is not limited to the example described above with reference to FIG. 14. In some embodiments, the support plate 220 may include a groove area 222, and a foam type adhesive part 224 may be disposed in the groove area 222 (see FIG. 15). For example, the foam type adhesive part 244 may have a thickness as compared with the double-sided adhesive part 242. By considering the thickness, the groove area 222 having a depth corresponding to the thickness may be formed in the support plate 220. In accordance with this embodiment, the support plate 220 and the heat dissipation part HSL may be coupled to each other by using the foam type adhesive part 244 having the thickness.

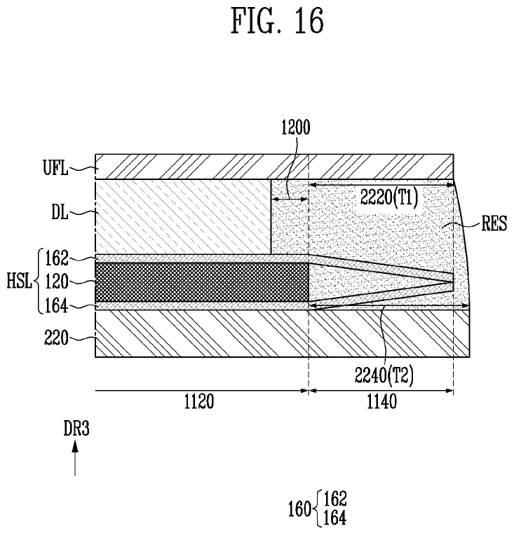

Continuously, referring to FIG. 16, the resin part RES may be provided (or disposed) at an outer portion of the display device DD.

The resin part RES may be sprayed to cover the heat dissipation layer 120. For example, the resin part RES may be sprayed to fill a space with respect to the second area 1140. The resin part RES may be sprayed to overlap the first area 1120 and the second area 1140.

In some embodiments, the resin part RES may be sprayed to fill one space of the first area 1120, in which the heat dissipation extension length 1200 may be defined. Accordingly, one side surfaces of the display layer DL and the heat dissipation part HSL can be covered (or sealed) by the resin part RES.

In accordance with an embodiment, the resin part RES may be sprayed by using a pneumatic valve. For example, the resin part RES may be sprayed by using a needle type valve. In case that the needle type valve may be used, the resin part RES may be suitable for being filled in a space. However, the above-described example is not necessarily limited thereto.

For example, in some embodiments, the resin part RES may be sprayed by using a jetting valve. Particularly, in an embodiment in which the support plate 220 may be disposed after the resin part RES may be provided, the resin part RES may be sprayed by using the jetting value.

The resin part RES may have a first thickness T1 at a film adjacent surface 2220. The first thickness T1 may correspond to a length of one area of the outer film layer UFL, which may not overlap the heat dissipation layer 120.

The resin part RES may have a second thickness T2 at an outer lower surface 2240. The second thickness T2 may be greater than the length of the one area of the outer film layer UFL, which may not overlap the heat dissipation layer 120.

In accordance with an embodiment, the resin part RES may be cured. For example, the resin part RES may receive heat provided by using UV or the like. The resin part RES may be cured according to the heat to be provided in a shape. Subsequently, in some embodiments, the support plate 220 may be removed.

In accordance with an embodiment, after the support plate 200 may be disposed on the bottom of the heat dissipation part HSL, the resin part RES may be provided, so that the thickness of the resin part RES can be sufficiently secured. The support plate 220 may physically support one surface (e.g., the bottom) of the resin part RES.

For example, the resin part RES may have a viscosity before the resin part RES may be cured. Therefore, the resin part RES may have a property that the resin part RES is to form a contact surface with another component. For example, the resin part RES may be diffused along a contact surface with the support plate 220, so that the outer lower surface 2240 of the resin part RES extends. Therefore, the second thickness T2 may be provided greater than the length of the one area of the outer film layer UFL, which may not overlap the heat dissipation layer 120.

For example, the resin part RES may have a sufficient thickness, and cover (or seal) the display layer DL and the heat dissipation layer 120. Accordingly, the light leakage phenomenon can be prevented, and the diffusion of particles of the heat dissipation layer 120 can be effectively prevented.

In accordance with the disclosure, there may be provided a display device and a manufacturing method for the same, which may be configured to improve process performance and reduce a light leakage phenomenon while sufficiently ensuring heat dissipation performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth herein.

What is claimed is:

1. A display device comprising:
a display layer including a light emitting element;
a heat dissipation part disposed on a rear surface of the display layer, the heat dissipation part including a heat dissipation layer; and
a resin part sealing at least a portion of the heat dissipation layer,
wherein, in a plan view, the heat dissipation layer extends by a same length as the display layer or extends farther than the display layer.

2. The display device of claim 1, wherein the heat dissipation layer includes graphite.

3. The display device of claim 1, wherein the heat dissipation part includes a cover layer sealing at least one surface of the heat dissipation layer.

4. The display device of claim 3, wherein the cover layer includes:
a first cover layer covering a surface of the heat dissipation layer; and
a second cover layer covering another surface of the heat dissipation layer.

5. The display device of claim 3, wherein
a surface of the heat dissipation layer is covered by the cover layer,
another surface of the heat dissipation layer is exposed by the cover layer, and
the heat dissipation layer is disposed between the display layer and the cover layer.

6. The display device of claim 3, further comprising:
a first area overlapping the heat dissipation layer in a plan view, and
a second area not overlapping the heat dissipation layer in a plan view, wherein
in a plan view, the display layer, the heat dissipation layer, and the cover layer overlap the first area, and
in a plan view, the resin part and the cover layer overlap the second area.

7. The display device of claim 6, wherein, in a plan view, the resin part overlaps the heat dissipation layer and the cover layer in a partial area of the first area.

8. The display device of claim 6, wherein
a surface of the display layer is covered by the heat dissipation layer, and
a side surface of the display layer is covered by the resin part.

9. The display device of claim 1, further comprising:
a first area overlapping the heat dissipation layer in a plan view; and
a second area not overlapping the heat dissipation layer in a plan view;
wherein, in a plan view, the resin part overlaps the cover layer in each of the first area and the second area.

10. The display device of claim 1, wherein the heat dissipation layer extends by a same length as the cover layer or extends farther than the cover layer in a direction.

11. The display device of claim 10, wherein
the heat dissipation layer extends farther by a heat dissipation extension length than the display layer, and
in a plan view, the resin part overlaps the heat dissipation layer and an area in which the heat dissipation extension length is defined.

12. The display device of claim 1, further comprising:
an outer film layer disposed on the display layer, wherein
the resin part includes a film adjacent surface adjacent to the outer film layer and an outer lower surface disposed at another side of the film adjacent surface, and
a thickness of the outer lower surface is greater than a thickness of the film adjacent surface in an extending direction of the outer film layer.

13. The display device of claim 6, further comprising:
an outer film layer disposed on the display layer, wherein
the resin part includes:
a film adjacent surface adjacent to the outer film layer; and
an outer lower surface disposed at another side of the film adjacent surface,
the film adjacent surface has a first thickness from a division point of the first area and the second area in an extending direction of the outer film layer,
the outer lower surface has a second thickness from the division point of the first area and the second area in the extending direction of the outer film layer,
the resin part has an average thickness defined from the division point of the first area and the second area in the extending direction of the outer film layer, and
the second thickness is greater than the average thickness.

14. The display device of claim 13, wherein the first thickness is smaller than the average thickness.

15. A display device comprising:
a display layer including a light emitting element;
a heat dissipation part disposed on a rear surface of the display layer, the heat dissipation part including a heat dissipation layer;
an outer film layer disposed on the display layer; and
a resin part sealing at least a portion of the heat dissipation layer, wherein
the resin part includes a film adjacent surface adjacent to the outer film layer and an outer lower surface disposed at another side of the film adjacent surface, and
a thickness of the outer lower surface is greater than an average thickness of the resin part in an extending direction of the outer film layer.

16. A method for manufacturing a display device, the method comprising:
providing a heat dissipation part on a rear surface of a display layer including a light emitting element;
cutting a portion of the heat dissipation part; and
providing a resin part, wherein
the heat dissipation part includes a heat dissipation layer and a cover layer,
the cutting of the portion of the heat dissipation part includes cutting the cover layer, and
the providing of the heat dissipation part includes disposing the heat dissipation layer to extend by a same length as the display layer or to extend farther than the display layer.

17. The method of claim 16, wherein the providing of the resin part includes:
sealing the heat dissipation layer; and
sealing the display layer.

18. The method of claim 16, further comprising:
disposing an outer film layer on the display layer, wherein
the providing of the heat dissipation part includes defining a first area, a second area, and a third area,
the first area overlaps the heat dissipation layer in a plan view,
the second area and the third area do not overlap the heat dissipation layer in a plan view, and
the cutting of the portion of the heat dissipation part includes removing a portion of the outer film layer and a portion of the cover layer, which overlap the third area in a plan view.

19. The method of claim 18, wherein, in a plan view, the portion of the outer film layer and the portion of the cover layer, which overlap the third area, are removed through a same cutting process.

20. The method of claim 16, further comprising:
disposing a support plate on a rear surface of the heat dissipation part.

21. The method of claim 20, wherein the disposing of the support plate is performed after the providing of the resin part.

22. The method of claim 20, wherein the disposing of the support plate is performed before the providing of the resin part.

23. The method of claim 20, wherein the support plate is attached to the heat dissipation part by a double-sided adhesive part.

24. The method of claim 20, wherein the support plate includes a groove area, and is attached to the heat dissipation part by a foam type adhesive part disposed in the groove area.

25. The method of claim 20, wherein
the providing of the heat dissipation part includes defining a first area, a second area, and a third area,
the first area overlaps the heat dissipation layer in a plan view,
the second area does not overlap the heat dissipation layer in a plan view, and
the providing of the resin part includes filling a space in which the resin part overlaps the second area in a plan view.

26. The method of claim 25, wherein the support plate physically supports a bottom of the resin part such that the resin part forms a contact surface with the support plate.

27. A display device manufactured by the method of claim 16.
